(19) United States
(12) Patent Application Publication
(10) Pub. No.: US 2022/0109084 A1
(43) Pub. Date: Apr. 7, 2022

(54) ELECTRONIC DEVICE

(71) Applicant: Au Optronics Corporation, Hsinchu (TW)

(72) Inventors: Chia-Wei Kuo, Hsinchu (TW); Ching-Huan Lin, Hsinchu (TW); Ching-Lang Hung, Hsinchu (TW)

(73) Assignee: Au Optronics Corporation, Hsinchu (TW)

(21) Appl. No.: 17/306,935

(22) Filed: May 3, 2021

(30) Foreign Application Priority Data
Oct. 6, 2020 (TW) 109134558

(51) Int. Cl. H01L 33/38; H01L 33/40; H01L 35/02; H01L 25/16

(52) U.S. Cl. CPC H01L 33/382; H01L 25/165; H01L 35/02; H01L 33/40

(57) ABSTRACT

An electronic device including a first substrate, a second substrate, a light-emitting element, and a piezoelectric element is provided. The light-emitting element is disposed between the first substrate and the second substrate. The piezoelectric element is disposed between the first substrate and the second substrate. The piezoelectric element includes a piezoelectric layer having an opening, and the light-emitting element is disposed in the opening.

### CROSS-REFERENCE TO RELATED APPLICATION

This application claims the priority benefits of Taiwan application serial no. 109134558, filed on Oct. 6, 2020. The entirety of the above-mentioned patent application is hereby incorporated by reference herein and made a part of this specification.

### BACKGROUND

### Technical Field

The disclosure relates to a device, and particularly to an electronic device.

### Description of Related Art

With the continuous improvement of science and technology, in addition to continuous breakthroughs in display and sound effects to provide richer sound and light stimuli, various electronic devices have constantly been developed for other sensory stimuli. For AI-related products, this developmental trend is even more necessary.

### SUMMARY

The present disclosure provides an electronic device capable of providing multiple functions.

The electronic device of the present disclosure includes a first substrate, a second substrate, a light-emitting element, and a piezoelectric element. The light-emitting element is disposed between the first substrate and the second substrate. The piezoelectric element is disposed between the first substrate and the second substrate. The piezoelectric element includes a piezoelectric layer having an opening, and the light-emitting element is provided in the opening.

The electronic device of the present disclosure includes a first substrate, a second substrate, a light-emitting element, and temperature control elements. The light-emitting element is disposed between the first substrate and the second substrate. The temperature control elements are disposed on a surface of the first substrate away from the second substrate. The temperature control elements are independently controllable.

Based on the above, the disclosed embodiment combines at least one of a piezoelectric element and a temperature control element with a light-emitting element to form an electronic device. In this way, the electronic device is capable of displaying images to provide visual stimuli, tactile, and temperature stimuli to the user, thereby enhancing the functions of the electronic device.

### BRIEF DESCRIPTION OF THE DRAWINGS

FIG. 1 is a schematic top view of an electronic device according to an embodiment of the disclosure.

FIG. 2 is a schematic partial cross-sectional view of an electronic device according to an embodiment of the disclosure.

FIG. 3 to FIG. 6 are schematic partial cross-sectional views of electronic devices according to different embodiments of the disclosure.

FIG. 7 to FIG. 10 are the manufacturing process of the electronic device according to an embodiment of the disclosure.

FIG. 11 is an exploded schematic diagram of a piezoelectric element according to an embodiment of the disclosure.

FIG. 12 is a schematic partial cross-sectional view of an electronic device according to another embodiment of the disclosure.

FIG. 13 is a schematic partial cross-sectional view of an electronic device according to yet another embodiment of the disclosure.

FIG. 14 to FIG. 17 are the schematic manufacturing process of the electronic device according to an embodiment of the disclosure.

FIG. 18 is an exploded schematic diagram of the piezoelectric layer, the first electrode, and the second electrode of the piezoelectric element 240 according to an embodiment of the disclosure.

FIG. 19 is a schematic top view of an electronic device according to another embodiment of the disclosure.

FIG. 20 is a schematic partial cross-sectional view of an electronic device according to an embodiment of the disclosure.

FIG. 21 is a schematic diagram of a plurality of temperature control elements disposed in an array according to an embodiment of the disclosure.

FIG. 22 is a schematic cross-sectional view of the temperature control element of FIG. 21 viewed from a section line A-A′.

FIG. 23 is a schematic diagram of a plurality of temperature control elements disposed in an array according to another embodiment of the disclosure.

FIG. 24 and FIG. 25 are schematic cross-sectional views of the temperature control element of FIG. 23 viewed from a section line B-B′ and a section line C-C′.

FIG. 26 is a schematic diagram of an electronic device according to still another embodiment of the disclosure.

### DESCRIPTION OF THE EMBODIMENTS

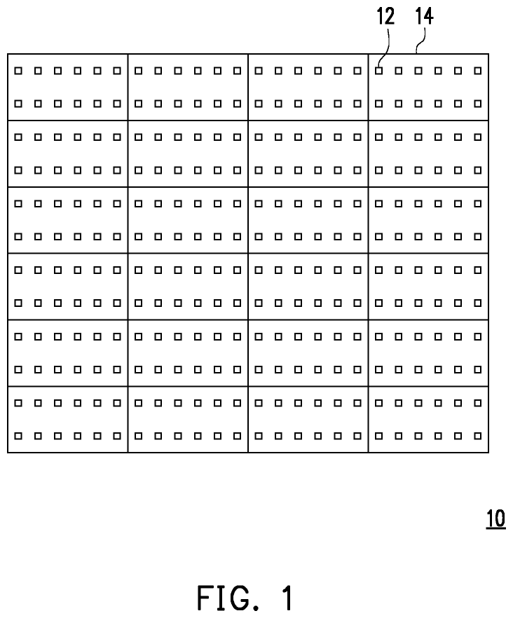

FIG. 1 is a schematic top view of an electronic device according to an embodiment of the disclosure. An electronic device 10 in FIG. 1 includes a plurality of light-emitting elements 12 and a plurality of piezoelectric elements 14, and the light-emitting elements 12 and the piezoelectric elements 14 are all disposed in an array. The light-emitting element 12 may be a micro light-emitting diode, a sub-millimeter light-emitting diode, or a similar light-emitting diode element. The light-emitting elements 12 may be controlled independently of each other and may include visible light-emitting diode elements of multiple colors, so as to achieve a colorful display effect. However, in some embodiments, the light-emitting elements 12 may all be light-emitting diode elements of the same color; in addition, the light-emitting element 12 may be matched with a wavelength conversion layer, a color filter layer, and other films or materials with light color adjustment functions to achieve different light colors, and the film or material with light color adjustment functions may be disposed on a light-emission path of the light-emitting element 12. The piezoelectric element 14 is an element capable of generating a piezoelectric effect. Specifically, the piezoelectric element 14 may vibrate after being electrically controlled to provide tactile stimuli to a user who touches the electronic device 10, or generate an electrical signal to sense the user's touch after the user touches the electronic device. Therefore, in addition to the visual stimuli (for example, by displaying images), the electronic device 10 may also provide the user with tactile stimuli (such as, vibration, friction, tactile sensing, etc.). In this embodiment, a plurality of piezoelectric elements 14 may be independently controlled, so that tactile stimuli may be provided regionally, making the functions of the electronic device 10 even more diversified. For example, different piezoelectric elements 14 may generate piezoelectric effects at different timing, or may each generate vibrations of different frequencies to provide multiple tactile stimuli.

The configuration density of the light-emitting element 12 and the piezoelectric element 14 may be determined based on the display effect needed by the electronic device 10 and the tactile stimulation effect to be provided. Generally speaking, the resolution required by the tactile stimulation function is lower than the resolution required by the display function, but the disclosure is not limited thereto. In this embodiment, the configuration density of the light-emitting elements 12 may be greater than the configuration density of the piezoelectric elements 14, and each piezoelectric element 14 may be designed to correspond to a plurality of light-emitting elements 12. For example, as shown in shown in FIG. 1, there are 4×6 piezoelectric elements 14 and there are 6×2 light-emitting elements 12 provided in the area of each piezoelectric element 14. The above numbers are only used to illustrate the configuration density of various elements, instead of limiting the numbers of the light-emitting element 12 and the piezoelectric element 14.

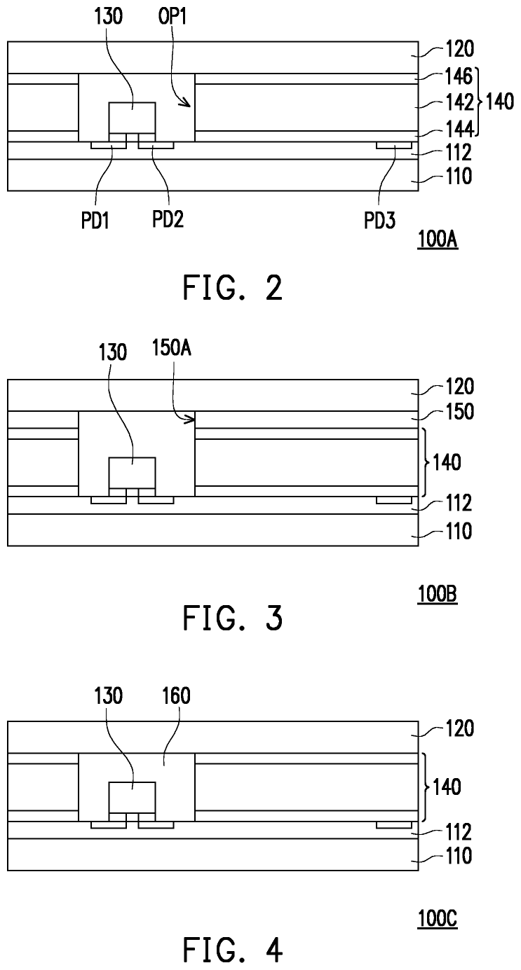

FIG. 2 is a schematic partial cross-sectional view of an electronic device according to an embodiment of the disclosure. In FIG. 2, an electronic device 100A may be adapted as an implementation of a cross-sectional structure of the electronic device 10 in FIG. 1, but the cross-sectional structure of the electronic device 10 is not limited thereto. The electronic device 100A may include a first substrate 110, a second substrate 120, a light-emitting element 130, and a piezoelectric element 140, where the light-emitting element 130 may be regarded as an embodiment of the light-emitting element 12 in FIG. 1 and the piezoelectric element 140 may be regarded as an embodiment of the piezoelectric element 14 in FIG. 1.

The first substrate 110 and the second substrate 120 are disposed face-to-face and sandwich the light-emitting element 130 and the piezoelectric element 140 therebetween. In other words, both the light-emitting element 130 and the piezoelectric element 140 are disposed between the first substrate 110 and the second substrate 120, whereas the first substrate 110 and the second substrate 120 protect, support, and carry the light-emitting element 130 and the piezoelectric element 140. As shown in FIG. 2, the light-emitting element 130 and the piezoelectric element 140 may be disposed in parallel between the first substrate 110 and the second substrate 120. In this way, the electronic device 100A may use the light-emitting element 130 to realize the screen display function, and use the piezoelectric element 140 to realize the function of tactile stimuli, such as vibration, friction, and the like. Specifically, the piezoelectric element 140 is, for example, an element including a piezoelectric layer 142, and the piezoelectric layer 142 has an opening OP1. The light-emitting element 130 is provided in the opening OP1 of the piezoelectric layer 142.

The first substrate 110 and the second substrate 120 may be plates with sufficient load capacity to protect the light-emitting element 130 and the piezoelectric element 140 from being damaged. In some embodiments, the materials of the first substrate 110 and the second substrate 120 include glass, quartz, sapphire, ceramics, polycarbonate (PC), polyimide (PI), polyimide Polyethylene terephthalate (PET), glass fiber, ceramics, other suitable substrate materials, or a combination of the foregoing. In addition, a driving circuit layer 112 may be provided on the first substrate 110, and the driving circuit layer 112 may include a circuit structure (not shown), pads PD1, PD2, and PD3, and a dielectric layer (not shown) for electrically insulating different circuit structures. The circuit structure in the driving circuit layer 112 may include circuit elements such as transistors, capacitors, transmission lines, and power lines, whereas the pads PD1, PD2, and PD3 are adapted to electrically connect other elements, such as the light-emitting element 130 and/or the piezoelectric element 140, to the circuit structure in the driving circuit layer 112.

The light-emitting element 130 may be a prefabricated light-emitting diode, and the light-emitting element 130 may be bonded to the pad PD1 and the pad PD2 on the first substrate 110 to be electrically connected to the circuit structure of the driving circuit layer 112. The light-emitting element 130 may be bonded to the pad PD1 and the pad PD2 by flip-chip bonding, wire bonding, or other alternative bonding methods. FIG. 2 shows the flip-chip bonding as an example, but the disclosure is not limited thereto. The light-emitting element 130 may be a light-emitting diode, a sub-millimeter light-emitting diode, or the like in some embodiments. The light-emitting element 130 may be a top emission light-emitting diode, a bottom emission light-emitting diode, or a double side emission light-emitting diode. The first substrate 110, the second substrate 120, or both that are provided on a light-emitting side of the light-emitting element 130 may be light-transmissive substrates that allow the light emitted by the light-emitting element 130 to pass through themselves. In addition, the electronic device 100A may actually include a plurality of light-emitting elements 130, and the light-emitting elements 130 may be adapted to emit light of different colors to achieve a multi-color display effect. In some embodiments, the light-emitting elements 130 may include visible light-emitting elements of different colors, such as any combination of red light-emitting elements, green light-emitting elements, blue light-emitting elements, cyan light-emitting elements, and yellow light-emitting elements. In other embodiments, at least part of the light-emitting elements 130 may be matched with different light color adjustment layers or light color adjustment materials to display the desired light-emitting color.

The piezoelectric element 140 includes the piezoelectric layer 142. In some embodiments, the material of the piezoelectric layer 142 includes piezoelectric single crystal, piezoelectric polycrystal (piezoelectric ceramic), piezoelectric polymer (such as, polyvinylidene fluoride epoxy resin, polyvinylidene fluoride (PVDF)), piezoelectric composite materials composed of piezoelectric ceramics and piezoelectric polymers. In order to control the piezoelectric performance of the piezoelectric layer 142, the piezoelectric element 140 further includes a first electrode 144 and a second electrode 146. In FIG. 2, the first electrode 144 and the second electrode 146 are provided on opposite sides of the piezoelectric layer 142, where the first electrode 144 is disposed between the first substrate 110 and the piezoelectric layer 142, and the second electrode 146 is disposed between the second substrate 120 and the piezoelectric layer 142. However, in other embodiments, the first electrode 144 and the second electrode 146 may also be disposed on the same side of the piezoelectric layer 142.

The first electrode 144 and the second electrode 146 may be electrically connected to the driving circuit layer 112 on the first substrate 110 to receive corresponding electrical signals. For example, the first electrode 144 may be connected to the pad PD3 on the driving circuit layer 112, and the circuit structure in the driving circuit layer 112 provides control signals to the first electrode 144. In addition, although not shown in the figure, the second electrode 146 may also be electrically connected to the circuit structure in the driving circuit layer 112 to receive the corresponding control signals.

When electrical signals are applied to the first electrode 144 and the second electrode 146, the piezoelectric layer 142 vibrates in response to the electrical signals, thereby providing tactile stimuli to the user. Also, the piezoelectric layer 142 may also generate electrical signals after vibration; therefore, the piezoelectric element 140 may be a capacitive micromachined ultrasonic transducer (CMUT) or a piezoelectric micromachined ultrasonic transducer (PMUT) to sense the user's touch. In some embodiments, the electrical signals input to the first electrode 144 has, for example, a first waveform, and the electrical signal input to the second electrode 146 has, for example, a second waveform, and the first waveform and the second waveform are different waveforms. For example, the first waveform and the second waveform may have different frequencies, phases, amplitudes, or any combination of the above. In another embodiment, one of the first waveform and the second waveform may be a direct current-type linear waveform, and the other may be a composite waveform.

The electronic device 100A uses the light-emitting element 130 to achieve the display function and the piezoelectric element 140 to provide tactile stimuli to the user. Therefore, the electronic device 100A may be widely used in various fields that need to provide users with multiple sensory stimuli. The configuration and design of the light-emitting element 130 and the piezoelectric element 140 may be adjusted according to different requirements. For example, the piezoelectric element 140 may further include dyes, colored particles, light-absorbing particles, etc. And the dyes, colored particles, light-absorbing particles, etc. may be doped in the piezoelectric layer 142 for the piezoelectric element 140 to further provide light absorption properties besides the piezoelectric properties. In this way, the piezoelectric element 140 is capable of absorbing and/or blocking unnecessary stray light to improve the display contrast of the electronic device 100A. Therefore, the electronic device 100A has good display and tactile stimulation functions.

FIG. 3 to FIG. 6 are schematic partial cross-sectional views of electronic devices according to various embodiments of the disclosure. An electronic device 100B in FIG. 3 is substantially similar to the electronic device 100A in FIG. 2, so the same components in the two embodiments are represented by the same component symbols. The electronic device 100B includes a first substrate 110 having a driving circuit layer 112, a second substrate 120, a light-emitting element 130, a piezoelectric element 140, and a light-absorbing layer 150. For the structure, arrangement relationship, and materials of the first substrate 110, the second substrate 120, the light-emitting element 130, and the piezoelectric element 140, please refer to the foregoing embodiments as they are not repeated herein. Compared with the electronic device 100A, the electronic device 100B further includes a light-absorbing layer 150. In this embodiment, the light-absorbing layer 150 may be disposed between the piezoelectric element 140 and the second substrate 120, and the light-absorbing layer 150 may have a light-absorbing-layer opening 150A. The position of the light-absorbing-layer opening 150A allows the light-emitting element 130 not to be shielded by the light-absorbing layer 150, so the light emitted by the light-emitting element 130 can pass through the light-absorbing-layer opening 150A and go through the second substrate 120. The arrangement of the light-absorbing layer 150 may absorb stray light, such as reflected light and scattered light that may exist around the light-emitting element 130, which helps improve the display contrast when the electronic device 100B displays images.

An electronic device 100C in FIG. 4 is substantially similar to the electronic device 100A in FIG. 2, so the same components in the two embodiments are represented by the same component symbols. The electronic device 100C includes a first substrate 110 having a driving circuit layer 112, a second substrate 120, a light-emitting element 130, a piezoelectric element 140, and a filling layer 160. For the structure, arrangement relationship, and materials of the first substrate 110, the second substrate 120, the light-emitting element 130, and the piezoelectric element 140, please refer to the foregoing embodiments as they are not repeated herein. The filling layer 160 may, for example, cover the light-emitting element 130 and fill the space between the light-emitting element 130, the first substrate 110, the second substrate 120, and the piezoelectric element 140.

In some embodiments, the filling layer 160 may be doped with phosphor or similar materials, and the light emitted by the light-emitting element 130 may have a shorter wavelength to excite the phosphor or the like that is added in the filling layer 160. Phosphors or similar materials may have a wavelength conversion function to convert the wavelength of the light emitted by the light-emitting element 130 into another wavelength, so as to achieve the desired color of light. In some embodiments, the light-emitting element 130 may be a blue light-emitting element, and the phosphor in the filling layer 160 may be red phosphor, green phosphor, yellow phosphor, cyan phosphor, or a combination of phosphor in multiple colors. In other words, when the phosphor is doped, the filling layer 160 disposed on the light-emission path of the light-emitting element 130 may act as a light color adjustment layer as it provides a light color adjustment function, but the disclosure is not limited thereto. In some embodiments, the filling layer 160 may be doped with scattering particles to scatter the light emitted by the light-emitting element 130 to different angles. In addition, in some embodiments, the electronic device 100C may further include the light-absorbing layer 150 in FIG. 3 to help improve the display contrast of the electronic device.

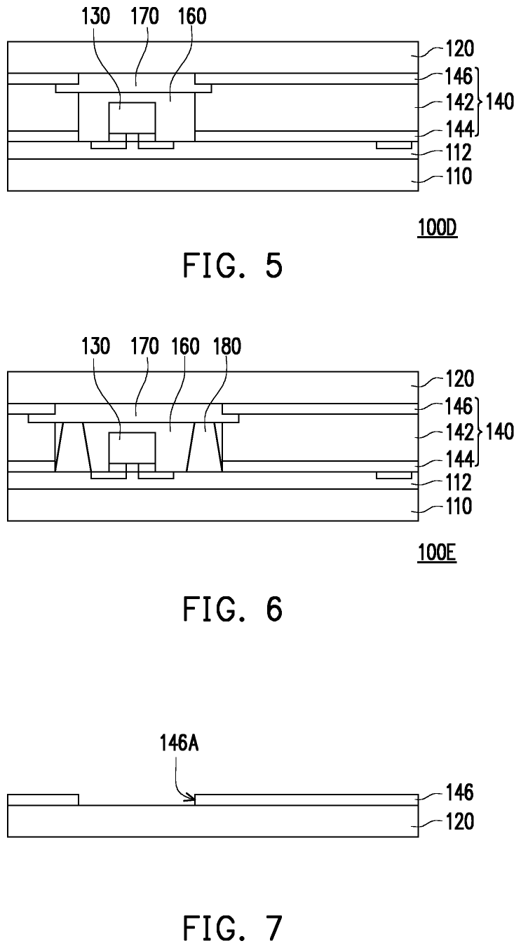

An electronic device 100D in FIG. 5 is substantially similar to the electronic device 100C in FIG. 4, so the same components in the two embodiments are represented by the same component symbols. The electronic device 100D includes a first substrate 110 having a driving circuit layer 112, a second substrate 120, a light-emitting element 130, a piezoelectric element 140 composed of a piezoelectric layer 142, a first electrode 144, and a second electrode 146, the filling layer 160, and the color filter layer 170. And for the structures, arrangement relationships and materials of the first substrate 110, the second substrate 120, the light-emitting element 130, the piezoelectric element 140, and the filling layer 160, please refer to the foregoing embodiment as they are not repeated herein. The color filter layer 170 is disposed between the filling layer 160 and the second substrate 120 and above the light-emitting element 130. The color filter layer 170 may filter the light emitted by the light-emitting element 130 and allow light of a specific wavelength to pass through itself to achieve the desired light-emitting color. The color filter layer 170 may include a red filter layer, a green filter layer, or filter layers in other visible light color. In other words, when the filling layer 160 is added with phosphor or similar materials, it provides light color adjustment, and the color filter layer 170 may also act as a light color adjustment layer as it also provides light color adjustment, but the disclosure is not limited thereto. In addition, in some embodiments, the electronic device 100D may further include the light-absorbing layer 150 in FIG. 3 to help improve the display contrast of the electronic device.

An electronic device 100E in FIG. 6 is substantially similar to the electronic device 100D in FIG. 5, so the same components in the two embodiments are represented by the same component symbols. The electronic device 100E includes a first substrate 110 having a driving circuit layer 112, a second substrate 120, a light-emitting element 130, a piezoelectric element 140 composed of a piezoelectric layer 142, a first electrode 144, and a second electrode 146, the filling layer 160, a color filter layer 170, and a bank 180. For the structures, arrangement relationships and materials of the first substrate 110, the second substrate 120, the light-emitting element 130, the piezoelectric element 140, the filling layer 160, and the color filer layer 170, please refer to the foregoing embodiment as they are not repeated herein. The banks 180 surround the light-emitting element 130 and are provided between the light-emitting element 130 and the piezoelectric element 140. In addition, the filling layer 160 may be filled between the bank 180 and the light-emitting element 130. In some embodiments, the manufacturing process of the electronic device 100E may include first forming the banks 180 and the light-emitting element 130 on the first substrate 110, and then assembling the first substrate 110 and the second substrate 120 on which the piezoelectric element 140 has been disposed to complete the electronic device 100E.

FIG. 7 to FIG. 10 are the manufacturing process of the electronic device according to an embodiment of the disclosure. FIG. 7 to FIG. 10 are to illustrate the manufacturing process of the electronic device 100A, but this can also be applied to the manufacturing process of the electronic devices 100B to 100E. In FIG. 7, the second electrode 146 is provided on a second substrate 120, where a second electrode 146 may be patterned and disposed in a predetermined area. In terms of FIG. 7, the second electrode 146 has an electrode opening 146A. In some embodiments, the second electrode 146 may be provided by deposition and photolithography, whereas in other embodiments, the second electrode 146 may also be made by printing. The material of the second electrode 146 includes a transparent conductive material, a metal conductive material, an organic conductive material, or other materials capable of conducting electricity and being patterned to be disposed in a predetermined area.

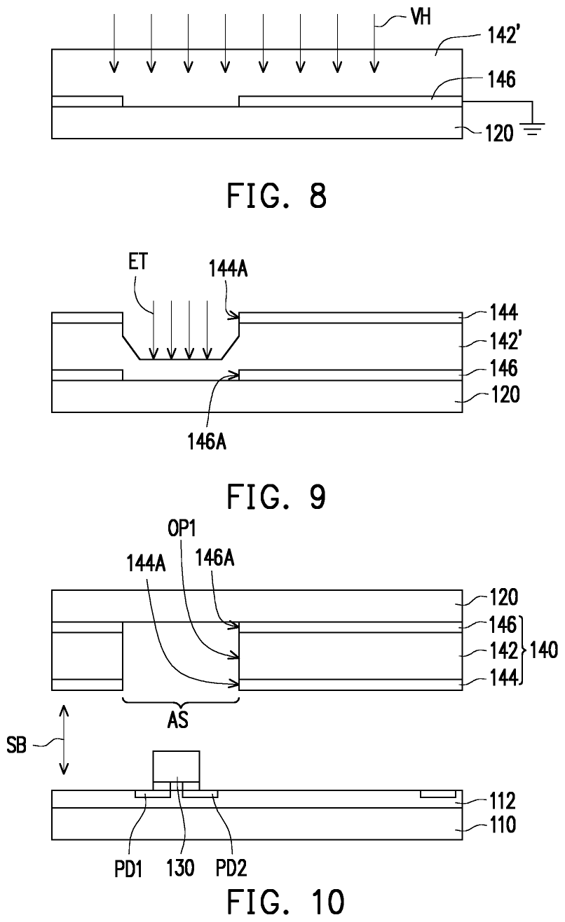

Next, in FIG. 8, a piezoelectric material layer 142′ is formed on the second substrate 120, and the piezoelectric material layer 142′ may directly contact the second electrode 146, but the disclosure is not limited thereto. The piezoelectric material layer 142′ is, for example, a piezoelectric polymer. In some embodiments, the piezoelectric material layer 142′ may be formed on the second substrate 120 by spin coating or film lamination. In addition, after the piezoelectric material layer 142′ is formed on the second substrate 120, a polarization process may be performed to polarize the piezoelectric material layer 142′. For example, the process of polarizing the piezoelectric material layer 142′ may be connecting the second electrode 146 to the ground potential, and an external electric field VH is provided to apply a high voltage to the piezoelectric material layer 142′ to rearrange the electric dipole moment of the piezoelectric material layer 142′ to have the piezoelectric properties as needed.

After that, as shown in FIG. 9, a first electrode 144 is formed on the piezoelectric material layer 142′, where the first electrode 144 is patterned to have an electrode opening 144A, and the electrode opening 144A exposes part of the piezoelectric material layer 142′. The electrode opening 144A of the first electrode 144 may correspond to the electrode opening 146A of the second electrode 146. Specifically, the area of the electrode opening 144A of the first electrode 144 projected orthographically onto the second substrate 120 may overlap with the area of the electrode opening 146A of the second electrode 146 projected orthographically onto the second substrate 120. Then, the first electrode 144 may be adapted as a mask to perform an etching process ET to remove the piezoelectric material layer 142′ exposed by the electrode opening 144A.

After the piezoelectric material layer 142′ is patterned by the process of FIG. 9, the piezoelectric layer 142 as shown in FIG. 10 is formed, where FIG. 10 shows the state of the second substrate 120 in FIG. 9 turned upside down. The piezoelectric layer 142 has an opening OP1 and is provided between the first electrode 144 and the second electrode 146, and the piezoelectric layer 142, the first electrode 144, and the second electrode 146 together constitute the piezoelectric element 140. The opening OP1 of the piezoelectric layer 142, the electrode opening 144A of the first electrode 144, and the electrode opening 146A of the second electrode 146 may correspond to one another to expose part of the second substrate 120. In this way, the piezoelectric element 140 and the second substrate 120 define an accommodating space AS.

After that, as shown in FIG. 10, an assembling process SB is performed to combine the second substrate 120 and the first substrate 110 together. Before the assembling step SB, the driving circuit layer 112 having a pad PD1, a pad PD2, and a pad PD3 may be pre-fabricated on the first substrate 110, and the light-emitting element 130 is pre-bonded on the pad PD1 and the pad PD2 of the driving circuit layer 112. The assembling process SB is, for example, attaching the first substrate 110 and the second substrate 120 to each other, so that the light-emitting element 130 is provided in the accommodating space AS formed by the second substrate 120 and the piezoelectric element 140, and to connect the first electrode 144 of the piezoelectric element 140 to the pad PD3 in the driving circuit layer 112. After the assembling process SB, the electronic device 100A shown in FIG. 2 is completed.

The above manufacturing process of the electronic device 100A is for illustrative purposes only, and the disclosure is not limited thereto. In some embodiments, when the manufacturing process of FIG. 7 to FIG. 10 is used to manufacture the electronic device 100B, the manufacturing process further includes forming the light-absorbing layer 150 on the second substrate 120 before the piezoelectric element 140 is manufactured. In some embodiments, when the manufacturing process of FIG. 7 to FIG. 10 is used to manufacture the electronic devices 100C to 100E, the manufacturing process further includes forming the filling layer 160 covering the light-emitting element 130 before assembling the first substrate 110 and the second substrate 120. In some embodiments, when the manufacturing process of FIG. 7 to FIG. 10 is used to manufacture the electronic device 100D or the electronic device 100E, the manufacturing process includes first forming the color filter layer 170 on the second substrate 120 after the second electrode 146 of the piezoelectric element 140 is formed on the second substrate 120, and then forming the piezoelectric layer 142 and the first electrode 144 of the piezoelectric element 140 on the second substrate 120. In some embodiments, when the manufacturing process of FIG. 7 to FIG. 10 is used to manufacture the electronic device 100E, the manufacturing process further includes forming the bank 180 on the first substrate 110 and forming the filling layer 160 between the bank 180 and the light-emitting element 130 before assembling the first substrate 110 and the second substrate 120. In addition, the above-mentioned patterning process of the piezoelectric material layer 142′ may adopt an additionally provided photoresist material as a mask and is not limited to using the first electrode 144 as a mask. In addition, in some embodiments, the piezoelectric layer 142 may be a piezoelectric ceramic, and the piezoelectric layer 142, the first electrode 144, and the second electrode 146 may be formed to be the independent piezoelectric element 140 in advance before being disposed on the second substrate 120 by transfer and attachment.

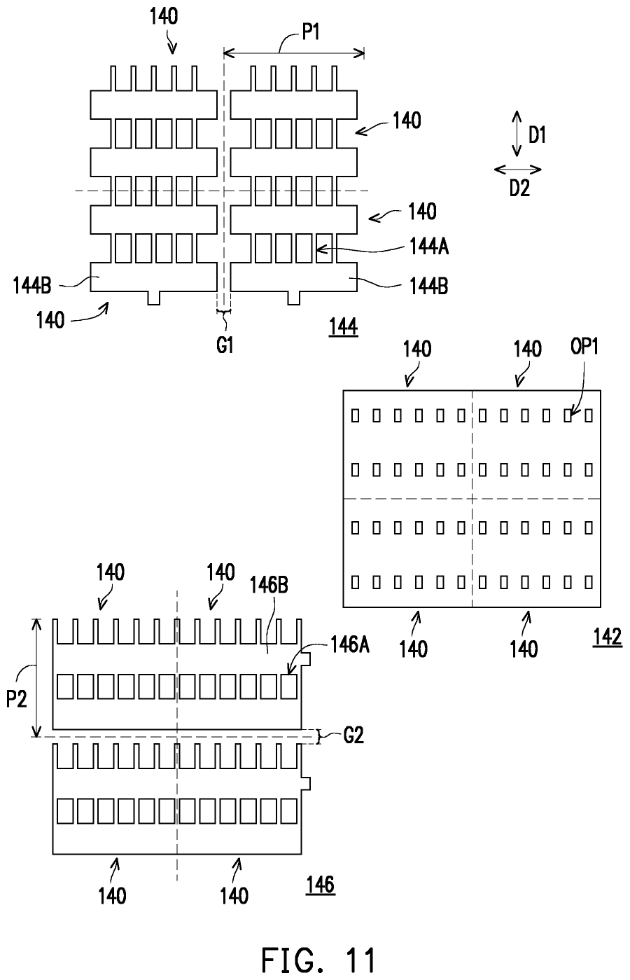

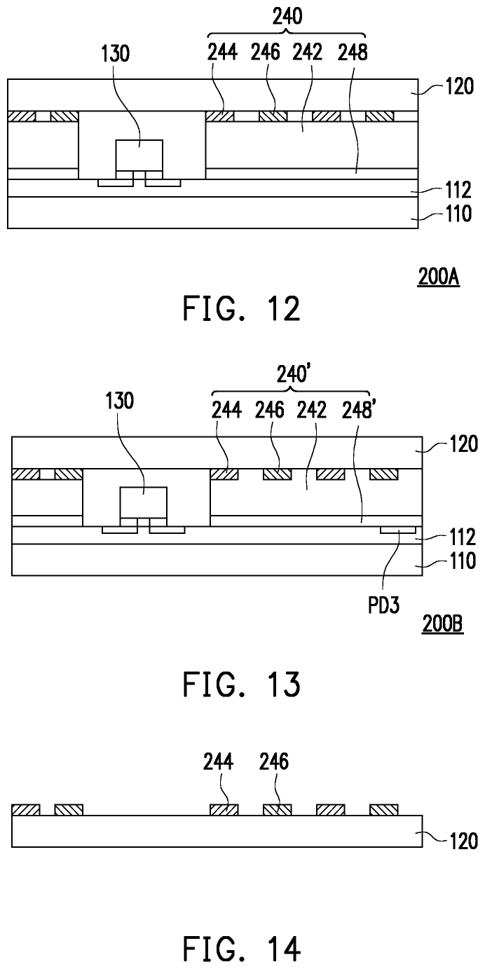

FIG. 11 is an exploded schematic diagram of a piezoelectric element according to an embodiment of the disclosure. FIG. 11 shows the design of four piezoelectric elements 140. The design of the piezoelectric element 140 in FIG. 11 may be applied to the piezoelectric element 14 and the piezoelectric element 140 of the foregoing embodiment, where the boundary of each of the piezoelectric element 140 is indicated by dashed lines. The four piezoelectric elements 140 may be composed of a piezoelectric layer 142, a first electrode 144, and a second electrode 146, respectively, and FIG. 11 shows a schematic top view of each layer of the piezoelectric layer 142, the first electrode 144, and the second electrode 146.

The piezoelectric layer 142 in FIG. 11 may continuously extend between the four piezoelectric elements 140. In other words, the piezoelectric layer 142 does not have to be disconnected between different piezoelectric elements 140, but the disclosure is not limited thereto. In addition, the piezoelectric layer 142 may have a plurality of openings OP1. As described in the foregoing embodiment, the openings OP1 of the piezoelectric layer 142 correspond to the light-emitting element in the electronic device and may be regarded as the installation area for the light-emitting element.

The first electrode 144 includes, for example, a plurality of first strip electrodes 144B, and each of the first strip electrodes 144B continuously extends along, for example, a first direction D1 to straddle the piezoelectric elements 140. Each of the first strip electrodes 144B may have a plurality of electrode openings 144A. For the arrangement of the electrode openings 144A, please refer to related descriptions in FIG. 7 to FIG. 10. Specifically, the electrode openings 144A provided on the first strip electrodes 144B may correspond to the openings OP1 in the piezoelectric layer 142 and correspond to the position of the light-emitting elements of the electronic device.

The adjacent first strip electrodes 144B are separated by an electrode gap G1, so that the adjacent first strip electrodes 144B are separated from one another in a second direction D2 (for example, they may intersect with each other or even be perpendicular to the first direction D1); therefore, the first strip electrodes 144B are electrically independent of one another. The electrode gap G1 is adapted for the adjacent first strip electrodes 144B to be electrically independent from one another, and its size may be determined by the process capability. In addition, a pitch P1 of the first strip electrode 144B in the second direction D2 may determine the pitch of the piezoelectric element 140 in the second direction D2. The pitch P1 is, for example, greater than 0.5 mm (millimeters), but the disclosure is not limited thereto. In other embodiments, the size of the pitch P1 may be determined according to the configuration density of the piezoelectric element 140 as needed.

The second electrode 146 includes, for example, the second strip electrodes 146B, and each of the second strip electrodes 146B continuously extends along, for example, the second direction D2 to straddle the piezoelectric elements 140, where the first direction D1 and the second direction D2 intersect each other. Each of the second strip electrodes 146B may have a plurality of electrode openings 146A. For the arrangement of the electrode openings 146A, please refer to the related descriptions of FIG. 7 to FIG. 10. Specifically, the electrode openings 146A provided on the second strip electrodes 146B may correspond to the openings OP1 in the piezoelectric layer 142, allowing the light-emitting elements to be disposed in the area of the electrode openings 146A.

The adjacent second strip electrodes 146B are separated by an electrode gap G2, so that the adjacent second strip electrodes 146B are separated from one another in the first direction D1; therefore, the second strip electrodes 146B are electrically independent of one another. The electrode gap G2 is adapted for the adjacent second strip electrodes 146B to be electrically independent from one another, and its size may be determined by the process capability. In addition, a pitch P2 of the second strip electrode 146B in the first direction D1 may determine the pitch of the piezoelectric element 140 in the first direction D1. The pitch P2 is, for example, greater than 0.5 mm (millimeters), but the disclosure is not limited thereto. In other embodiments, the size of the pitch P2 may be determined according to the configuration density of the piezoelectric element 140 as needed.

FIG. 12 is a schematic partial cross-sectional view of an electronic device according to another embodiment of the disclosure. An electronic device 200A in FIG. 12 includes a first substrate 110, a second substrate 120, a light-emitting element 130, and a piezoelectric element 240. The design of the electronic device 200A may be an implementation of a cross-sectional structure of the electronic device 10 in FIG. 1, such that the layout of the light-emitting element 130 and the piezoelectric element 240 in the top view may be as shown in FIG. 1. In addition, the electronic device 200A is substantially similar to the electronic device 100A, and for the arrangement relationship, material, structure, etc. of the first substrate 110, the second substrate 120, and the light-emitting element 130, please refer to the description of FIG. 2 to FIG. 10. For example, the first substrate 110 may be provided with a driving circuit layer 112, and the light-emitting element 130 may be disposed on the first substrate 110 and electrically connected to the driving circuit layer 112.

Compared to the electronic device 100A, the electronic device 200A is mainly different in its design of the piezoelectric element 240. Specifically, the piezoelectric element 240 of the electronic device 200A includes a piezoelectric layer 242, a first electrode 244, a second electrode 246, and a barrier layer 248. The material of the piezoelectric layer 242 may be the same as the material of the aforementioned piezoelectric layer 142. However, in this embodiment, the first electrode 244 and the second electrode 246 are both provided on the same side of the piezoelectric layer 242, while the barrier layer 248 is provided on the other side of the piezoelectric layer 242. For example, the first electrode 244 and the second electrode 246 are both provided between the piezoelectric layer 242 and the second substrate 120, and the barrier layer 248 is provided between the piezoelectric layer 242 and the first substrate 110. In this embodiment, the driving circuit layer 112 on the first substrate 110 does not have to be electrically connected to the barrier layer 248; therefore, the barrier layer 248 may be made of a conductive material or an insulating material, and the pad PD3 in the foregoing embodiment may be omitted in this embodiment. In this way, in the electronic device 200A, the piezoelectric layer 242 of the piezoelectric element 240 may receive electrical signals of the first electrode 244 and the second electrode 246 on the same side to generate a piezoelectric effect.

FIG. 13 is a schematic partial cross-sectional view of an electronic device according to yet another embodiment of the disclosure. An electronic device 200B in FIG. 13 includes a first substrate 110, a second substrate 120, a light-emitting element 130, and a piezoelectric element 240′. Specifically, the electronic device 200B is substantially similar to the electronic device 200A, but a barrier layer 248′ of the piezoelectric element 240′ in the electronic device 200B is made of conductive material and may be electrically connected to a driving circuit layer 112 on the first substrate 110. Therefore, the driving circuit layer 112 on the first substrate 110 has a pad PD3 connected to the barrier layer 248′. And, in the electronic device 200B, the piezoelectric layer 242 of the piezoelectric element 240′ may be controlled by the electrical signals of the first electrode 244, the second electrode 246, and the barrier layer 248′ to generate a piezoelectric effect.

FIG. 14 to FIG. 17 are the manufacturing process of an electronic device according to an embodiment of the disclosure. FIG. 14 to FIG. 17 are to illustrate the manufacturing process of the electronic device 200A, but this can also be applied to the manufacturing process of the electronic device 200B. FIG. 14 shows a process of forming a first electrode 244 and a second electrode 246 on a second substrate 120. In some embodiments, the first electrode 244 and the second electrode 246 may be formed by patterning the same conductive layer, and are disposed on the same plane, but the disclosure is not limited thereto. In addition, the first electrode 244 and the second electrode 246 may be alternately disposed on the second substrate 120. The materials of the first electrode 244 and the second electrode 246 may include metal, a transparent conductive material, and/or a combination of multiple conductive materials, such as a stack of multiple layers of conductive materials.

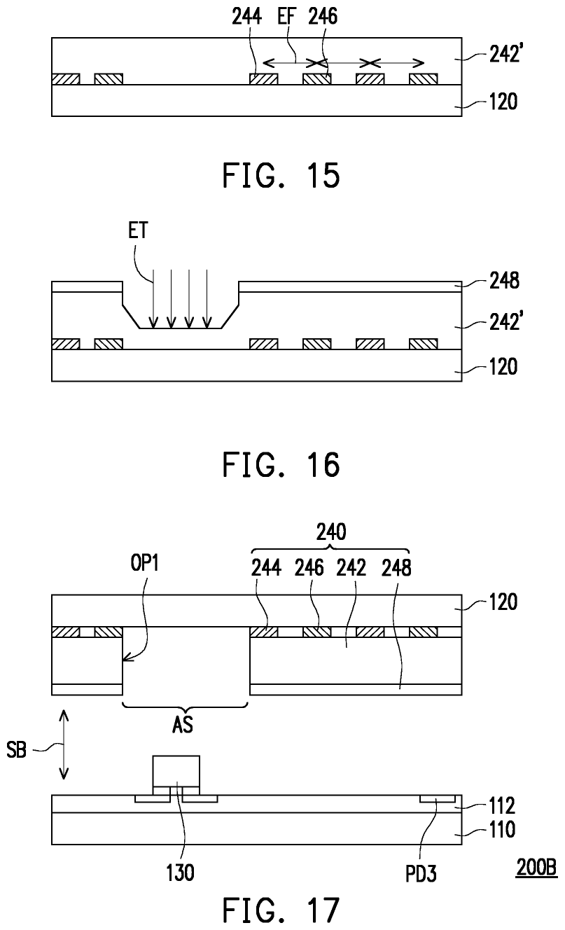

In FIG. 15, a piezoelectric material layer 242′ is formed on the second substrate 120. For the process for forming the piezoelectric material layer 242′, please refer to the process of forming the piezoelectric material layer 142′ in the foregoing embodiment. The piezoelectric material layer 242′ may be formed on the second substrate 120 by being coated on the entire surface to contact the first electrode 244 and the second electrode 246, but the disclosure is not limited thereto. Furthermore, after the piezoelectric material layer 242′ is formed on the second substrate 120, a polarization process may be performed to polarize the piezoelectric material layer 242′. For example, a voltage may be applied to the first electrode 244 and the second electrode 246, such that the piezoelectric material layer 242′ is polarized by an electric field EF generated by the first electrode 244 and the second electrode 246. Since the first electrode 244 and the second electrode 246 are on the same plane, the polarization direction of the piezoelectric material layer 242′ may be different from the polarization direction of the piezoelectric material layer 142′ in the foregoing embodiment. However, similar to the piezoelectric material layer 142′ of the foregoing embodiment, after being polarized, the piezoelectric material layer 242′ here generates the piezoelectric effect as needed under the control of the first electrode 244 and the second electrode 246.

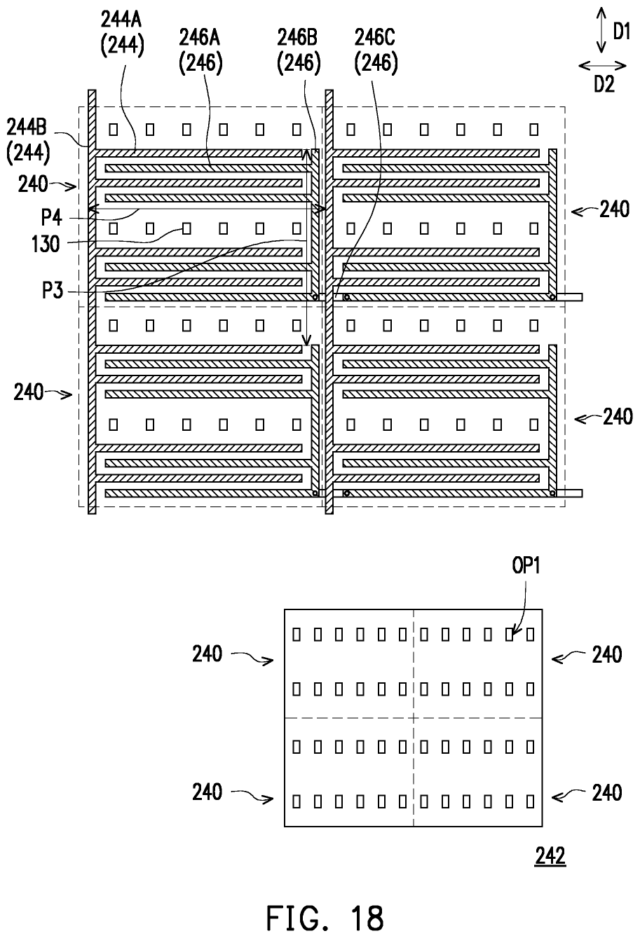

In FIG. 16, a barrier layer 248 is formed on the second substrate 120. The barrier layer 248 may be adapted subsequently as a mask, and an etching process ET is performed to remove part of the piezoelectric material layer 242′ that is not covered by the barrier layer 248. In some embodiments, the material of the barrier layer 248 includes dielectric materials, conductive materials, and other materials that are not easily removed in the process of etching the piezoelectric material layer 242′. The barrier layer 248 has, for example, a predetermined pattern to expose part of the piezoelectric material layer 242′. In other words, the part of the piezoelectric material layer 242′ that is shielded by the barrier layer 248 remains on the second substrate 120 to form a piezoelectric layer 242 as shown in FIG. 17, whereas the removed part of the piezoelectric material layer 242′ forms an opening OP1. In this way, the piezoelectric element 240 composed of the piezoelectric layer 242, the first electrode 244, the second electrode 246, and the barrier layer 248 is formed on the second substrate 120, and the opening OP1 of the piezoelectric layer 242 and the second substrate 120 define an accommodating space AS.

In FIG. 17, an assembly process SB is performed to assemble the second substrate 120 on which the piezoelectric element 240 has been formed and the first substrate 110 on which the drive circuit layer 112 and the light-emitting element 130 has been formed. In this embodiment, the assembly of the first substrate 110 and the second substrate 120 is, for example, to dispose the light-emitting element 130 in the accommodating space AS on the second substrate 120, and attach the barrier layer 248 to the driving circuit layer 112. When the electronic device 200A of FIG. 12 is manufactured using the manufacturing process of FIG. 14 to FIG. 17, the barrier layer 248 is not electrically connected to the driving circuit layer 112, and may be made of insulating materials or conductive materials, and the pad PD3 in the driving circuit layer 112 may be omitted. When the electronic device 200B of FIG. 13 is manufactured using the manufacturing process of FIG. 14 to FIG. 17, the driving circuit layer 112 on the first substrate 110 may be pre-formed with the pad PD3, and the barrier layer 248′ may be made with a conductive material, allowing the barrier layer 248′ to be electrically connected to the driving circuit layer 112. In other embodiments, the barrier layer 248 may be removed before the assembly process SB, and thus the piezoelectric layer 242 may be directly attached to the driving circuit layer 112 without the barrier layer 248 being disposed between the piezoelectric layer 242 and the driving circuit layer 112. In other words, the piezoelectric element 240 may be mainly composed of the piezoelectric layer 242, the first electrode 244, and the second electrode 246.

FIG. 18 is an exploded schematic diagram of a piezoelectric layer, a first electrode, and a second electrode of a piezoelectric element 240 according to an embodiment of the disclosure. And FIG. 18 also shows the layout relationship of a light-emitting element 130, a first electrode 244, and a second electrode 246. FIG. 18 mainly shows the layout design of the piezoelectric layer, the first electrode, and the second electrode in the piezoelectric element 240 in a top view, and FIG. 18 shows the layout of four piezoelectric elements 240, but they are not intended to limit the present disclosure. The design of the piezoelectric element 240 in FIG. 18 may be applied to the piezoelectric element 14 and the piezoelectric elements 240, 240′ of the foregoing embodiments.

In FIG. 18, the dashed lines indicate the boundary of the piezoelectric element 240, and the light-emitting elements 130 may be provided in the area of each piezoelectric element 240. In FIG. 18, a piezoelectric layer 242 may be continuously distributed in the four piezoelectric elements 240, that is, the piezoelectric layer 242 are not disconnected or separated in different piezoelectric elements 240. The piezoelectric layer 242 has a plurality of openings OP1, and each of the openings OP1 corresponds to, for example, one light-emitting element 130. The area of each piezoelectric element 240 in FIG. 18 may be provided with 2×6 light-emitting elements 130, but the disclosure is not limited thereto.

The first electrode 244 and the second electrode 246 are disposed on the same plane. The first electrode 244 has a first comb pattern 244A, and the second electrode 246 has a second comb pattern 246A. The first comb patterns 244A and the second comb patterns 246A are alternately disposed along a first direction D1, presenting two rows of comb patterns as in FIG. 18. Each of the first comb patterns 244A and the second comb patterns 246A is, for example, a strip electrode pattern extending along a second direction D2, and the extension length of each of the first comb patterns 244A and the second comb patterns 246A does not exceed, for example, a single piezoelectric element 240 and does not straddle other piezoelectric elements 240. In the installation area for the light-emitting element 130, the configuration density of the first comb electrode 244A and the second comb electrode 246A may be reduced, so as to reduce the interference of the electric signals of the first electrode 244 and the second electrode 246 on the light-emitting element 130, but the disclosure is not limited thereto.

The first electrode 244 also has a first connection pattern 244B, which connects the first comb patterns 244A together. The first connection pattern 244B may extend toward the first electrode 244 of the adjacent piezoelectric element 240 to be connected to the first electrode 244 of the adjacent piezoelectric element 240, connecting the first electrodes 244 disposed in the first direction D1 together. In other words, the first electrodes 244 disposed along the first direction D1 may be electrically connected to each other, but the disclosure is not limited thereto.

The second electrode 246 also has a second connection electrode 246B, which connects the second comb patterns 246A in the same piezoelectric element 240 together. In addition, the second electrode 246 may further include a bridging pattern 246C, and the bridging pattern 246C connects the second electrodes 246 of the piezoelectric elements 240 adjacent in the second direction D2 together. The bridging pattern 246C may straddle the first connection pattern 244B of the first electrode 244. In some embodiments, a film layer of the bridging pattern 246C may be different from a film layer of the first connection pattern 244B, and the bridging pattern 246C and the first connecting pattern 244B may be separated by an insulating layer (not shown). In addition, in some embodiments, the first comb pattern 244A, the first connection pattern 244B, the second comb pattern 246A, and the second connection pattern 246B of the same piezoelectric element 240 may be the same film layer, but the disclosure is not limited thereto.

In FIG. 18, the first electrode 244 and the second electrode 246 are provided as a pair and may be adapted to control the corresponding piezoelectric element 240. Each of the piezoelectric elements 240 may be independently controlled to provide local tactile stimuli. The size of the first electrode 244 and the second electrode 246 and the distribution density of the first comb pattern 244A and the second comb pattern 246A may be determined according to the resolution as needed. In some embodiments, in order for the user to feel the tactile stimuli provided by the piezoelectric element 240 when it is touched by a hand, a pitch P3 in the first direction D1 and a pitch P4 in the second direction D2 between the first electrode 244 and the second electrode 246 may be greater than 0.5 mm, but the disclosure is not limited thereto.

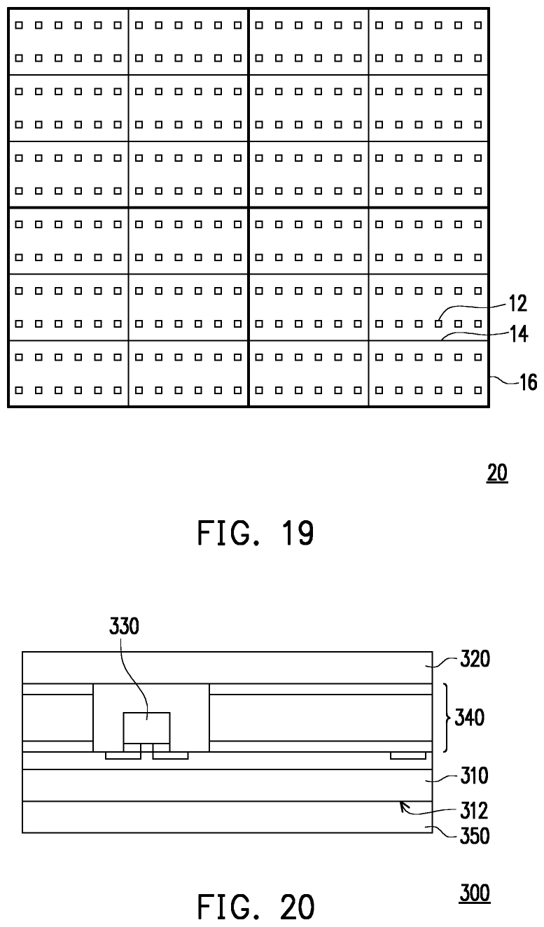

FIG. 19 is a schematic top view of an electronic device according to another embodiment of the disclosure. An electronic device 20 of FIG. 19 includes a plurality of light-emitting elements 12, a plurality of piezoelectric elements 14, and a plurality of temperature control elements 16, where the configuration, layout, structure, material, and cross-sectional structure of the light-emitting element 12 and the piezoelectric element 14 may be implemented by applying the design of the light-emitting element and the piezoelectric element in any of the foregoing embodiments. For example, the layout relationship between the light-emitting element 12 and the piezoelectric element may be as described in the embodiment of FIG. 1; the cross-sectional structure of the light-emitting element 12 and the piezoelectric element 14 may be as described in any one of the embodiments in FIG. 2 to FIG. 6 and FIG. 12 to FIG. 13; the manufacturing process of the light-emitting element 12 and the piezoelectric element 14 may be as described in the embodiments of FIG. 7 to FIG. 10 or FIG. 14 to FIG. 17; and the electrode design of the piezoelectric element 14 may be as shown in FIG. 11 or FIG. 18.

Specifically, the main difference between the electronic device 20 and the foregoing embodiment is that the electronic device 20 further includes the temperature control elements 16. The boundary of the temperature control element 16 is schematically represented by a thick line in FIG. 19 to show clearly the arrangement relationship of the temperature control element 16, the light-emitting element 12, and the piezoelectric element 14; however, the thick line in FIG. 19 is not used to limit the outline and position of the actual boundary of the temperature control element 16. In this embodiment, the light-emitting element 12 is used to emit light to display images and provide visual stimuli to the user. The piezoelectric element 14 is used to generate a vibration under the control of an electric field to provide mechanical stimulation (such as vibration, friction, etc.) on the user's touch, or to generate a corresponding signal based on the external vibration to feel the user's touch. In addition, the temperature control element 16 may have heat absorbing or exothermic properties to provide the user with tactile temperature stimuli (for example, feelings of cold and heat). Therefore, the electronic device 20 may have multiple functions, such as image display, mechanical vibration, and temperature change, etc.

The temperature control elements 16 may be independently controlled to provide local temperature stimuli, which makes the application of the electronic device 20 even more diversified. For example, when the electronic device 20 uses the light-emitting element 12 to display a cup of hot coffee and a glass of icy juice at the same time, the temperature control element 16 may release heat in the area where the hot coffee is displayed and absorb heat in the area where the icy juice is displayed, so that the user can feel different temperatures when touching the hot coffee screen and the ice juice screen, and such is one of the examples how the present disclosure provides diversified functions.

The configuration density needed by the light-emitting element 12, the piezoelectric element 14, and the temperature control element 16 may be different based on the difference of each function. For example, when the light-emitting element 12 is used to display an image, its configuration density needs to be sufficient for the eye to perceive the continuity of the image; when the piezoelectric element 14 is used to provide tactile vibration stimuli, its configuration density needs to correspond to the pressing area of the user's finger; and when the temperature control element 16 is used to generate different temperatures, its configuration area may be greater than the finger pressing area. Therefore, the configuration density of the light-emitting element 12 may be greater than the configuration density of the piezoelectric element 14, and the configuration density of the piezoelectric element 14 may be greater than the configuration density of the temperature control element 16. For example, FIG. 19 shows 2×2 temperature control elements 16, where one temperature control element 16 corresponds to 2×3 piezoelectric elements 14, and one piezoelectric element 14 corresponds to 6×2 light-emitting elements 12. The above numbers are only used to illustrate the configuration density of different elements, instead of limiting the numbers of the light-emitting element 12 and the piezoelectric element 14. In addition, in some embodiments, the electronic device 20 omits the piezoelectric element 14 and/or add other functional elements based on design requirements.

FIG. 20 is a schematic partial cross-sectional view of an electronic device according to an embodiment of the disclosure. And FIG. 20 may be adapted as an embodiment of the cross-sectional structure of the electronic device 20 in FIG. 19. In FIG. 20, an electronic device 300 may include a first substrate 310, a second substrate 320, a light-emitting element 330, a piezoelectric element 340, and a temperature control element 350. Both the light-emitting element 330 and the piezoelectric element 340 are disposed between the first substrate 310 and the second substrate 320, and specifically, the first substrate 310, the second substrate 320, the light-emitting element 330, and the piezoelectric element 340 may be implemented using the structure described in any one of the embodiments in FIG. 2 to FIG. 6 and FIG. 12 to FIG. 13. Furthermore, the temperature control element 350 is disposed on a surface 312 of the first substrate 310 that is away from the second substrate 320. In other words, the temperature control element 350 may be disposed on the outer surface of the first substrate 310. The layout of the electronic device 300 in the top view may be as the electronic device 20 in FIG. 19, as the numbers of the light-emitting element 330, the piezoelectric element 340, and the temperature control element 350 may all be multiple.

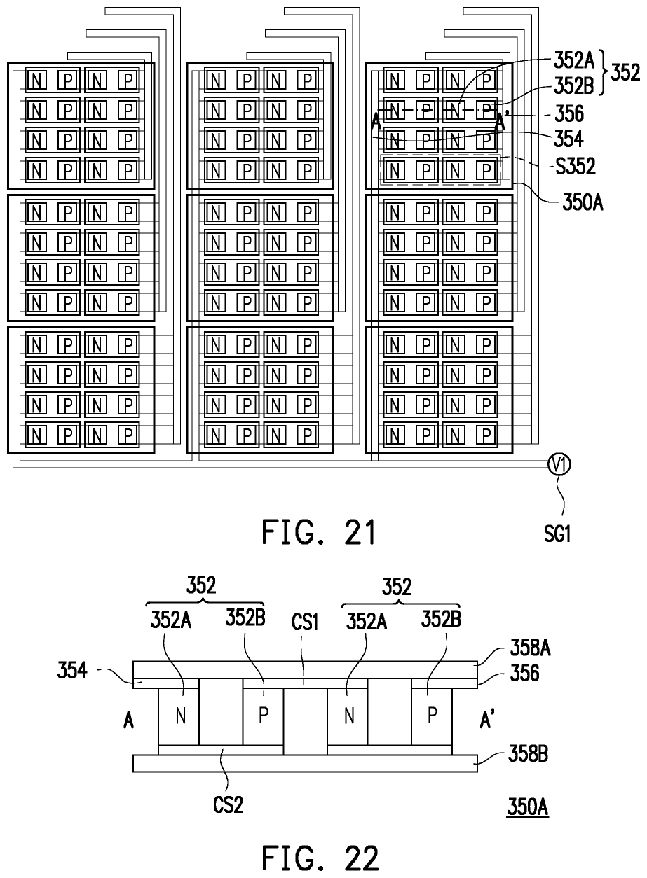

FIG. 21 is a schematic diagram of a plurality of temperature control elements disposed in an array according to an embodiment of the disclosure. The temperature control element in FIG. 21 may be applied to, for example, the electronic device in FIG. 19 and may be adapted as an implementation of the temperature control element 350 of FIG. 20. A temperature control element 350A of FIG. 21 includes a thermoelectric module 352, a first electrode 354, and a second electrode 356, where the thermoelectric module 352 includes an n-type semiconductor 352A and a p-type semiconductor 352B. The n-type semiconductor 352A and the p-type semiconductor 352B are electrically connected in series and connected between the first electrode 354 and the second electrode 356. Specifically, the temperature control element 350A may include multiple sets of thermoelectric modules 352, and the thermoelectric modules 352 are disposed into a plurality of rows 5352, and the rows 5352 are connected in parallel between the first electrode 354 and the second electrode 356. The materials of the n-type semiconductor 352A and the p-type semiconductor 352B include bismuth telluride and its alloys, lead telluride and its alloys, and silicon germanium.

Also, in FIG. 21, the temperature control element 350A is only schematically represented by a thick black frame, but it is not used to limit the actual outline of the temperature control element 350A.

The first electrode 354 and the second electrode 356 of the temperature control element 350A may be applied with different voltages to generate current flowing through the rows 5352, and the thermoelectric module 352 in the rows 5352 may have the heat-absorption or heat-release effects based on the flow direction of the current to implement the temperature adjustment function. FIG. 21 shows an array of 3×3 temperature control elements 350A, and the first electrodes 354 of these temperature control elements 350A may be connected to the same signal source SG1, whereas the second electrodes 356 of these temperature control elements 350A may be independently connected to different control sources. In this way, different temperature control elements 350A operate independently to provide different temperature adjustment functions, so as to generate different temperatures in different regions, and realize the design of local temperature stimuli.

FIG. 22 is a schematic cross-sectional view of the temperature control element of FIG. 21 viewed from a section line A-A′. It may be seen from FIG. 21 and FIG. 22 that the temperature control element 350A may be supported and carried by a third substrate 358A and a fourth substrate 358B, and the thermoelectric modules 352, the first electrode 354, and the second electrode 356 are disposed between the third substrate 358A and the fourth substrate 358B. The materials of the third substrate 358A and the fourth substrate 358B include insulating ceramic materials, aluminum oxide (Al₂O₃), aluminum nitride (AlN), or a combination thereof. When the temperature control element of FIG. 22 is configured in the electronic device 300 of FIG. 20, the third substrate 358A may be attached to the surface 312 of the first substrate 310. In other words, besides the first substrate 310 and the second substrate 320 that clamp the light-emitting element 330 and the piezoelectric element 340, the electronic device 300 may further include the third substrate 358A and the fourth substrate 358B that clamp the temperature control element 350.

In addition, it may be seen from FIG. 22 that the n-type semiconductor 352A and the p-type semiconductor 352B may be disposed alternately, and there is an air gap between the n-type semiconductor 352A and the p-type semiconductor 352B, but the disclosure is not limited thereto. The n-type semiconductor 352A and the p-type semiconductor 352B may be connected in series through a connecting conductor CS1 provided on the third substrate 358A and a connecting conductor CS2 provided on the fourth substrate 358B. In this embodiment, the connecting conductor CS1, the connecting conductor CS2, the first electrode 354, and the second electrode 356 may be made of copper, but the disclosure is not limited thereto.

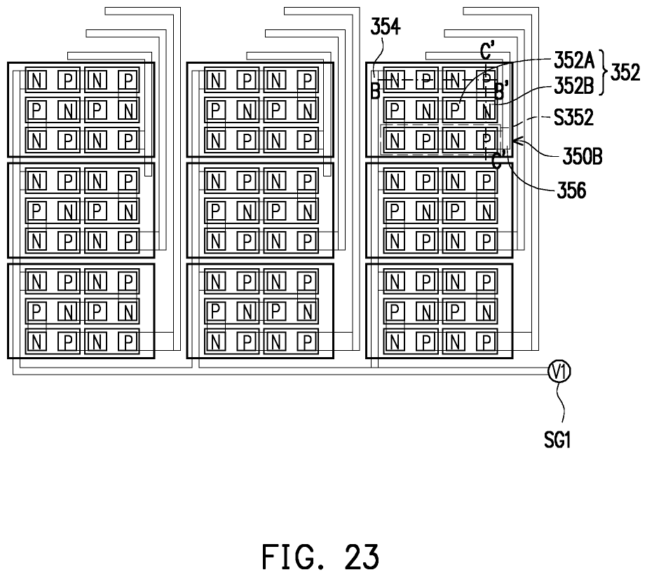

FIG. 23 is a schematic diagram of a plurality of temperature control elements disposed in an array according to another embodiment of the disclosure. The temperature control element in FIG. 23 may be applied to, for example, the electronic device in FIG. 19 and may be adapted as an implementation of the temperature control element 350 of FIG. 20. A temperature control element 350B of FIG. 23 includes a thermoelectric module 352, a first electrode 354, and a second electrode 356, where the thermoelectric module 352 includes an n-type semiconductor 352A and a p-type semiconductor 352B. The n-type semiconductor 352A and the p-type semiconductor 352B are electrically connected in series and connected between the first electrode 354 and the second electrode 356. Specifically, the temperature control element 350B may include multiple thermoelectric modules 352, and the thermoelectric modules 352 are disposed into a plurality of rows 5352, and the rows 5352 are connected in series between the first electrode 354 and the second electrode 356. In other words, compared with the temperature control element 350A, the temperature control element 350B is different in its connection mode of the rows 5352. For example, the rows 5352 in each of the temperature control elements 350B in FIG. 23 are connected into one string, whereas the rows 5352 in each of the temperature control elements 350A in FIG. 22 are each connected in a string.

The first electrode 354 and the second electrode 356 of the temperature control element 350B may be applied with different voltages to generate current flowing through the rows 5352, and the thermoelectric modules 352 may have the heat-absorption or heat-release effects based on the flow direction of the current to implement the temperature adjustment function. FIG. 23 shows an array of 3×3 temperature control elements 350B, and the first electrodes 354 of these temperature control elements 350B may be connected to the same signal source, whereas the second electrodes 356 of these temperature control elements 350B may be independently connected to different signal sources. In this way, different temperature control elements 350B may operate independently to provide different temperature in different regions and realize the design of local temperature stimuli.

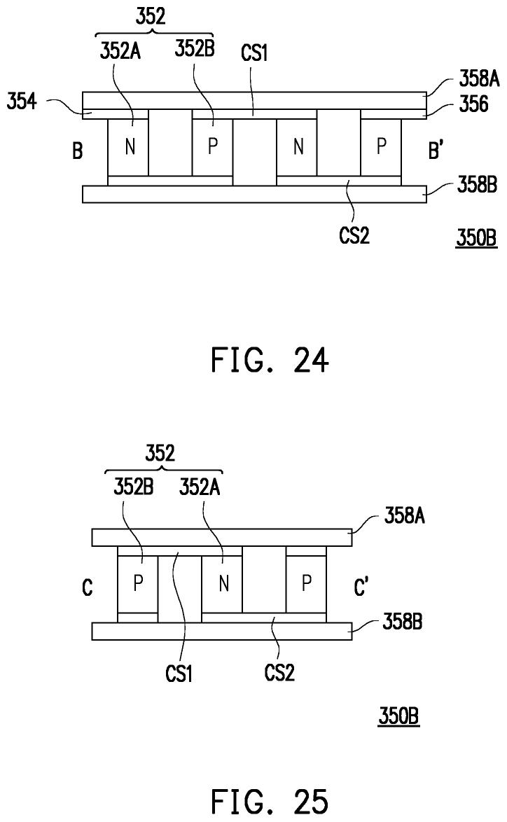

FIG. 24 and FIG. 25 are schematic cross-sectional views of the temperature control element of FIG. 23 viewed from a section line B-B′ and a section line C-C′. It may be seen from FIG. 23 and FIG. 25 that the temperature control element 350B may be disposed between the third substrate 358A and the fourth substrate 358B, and the thermoelectric modules 352, the first electrode 354, and the second electrode 356 are disposed between the third substrate 358A and the fourth substrate 358B. When the temperature control element of FIG. 23 and FIG. 24 is configured in the electronic device 300 of FIG. 20, the third substrate 358A may be attached to the surface 312 of the first substrate 310, but the disclosure is not limited thereto. In addition, it may be seen from FIG. 24 and FIG. 25 that the n-type semiconductor 352A and the p-type semiconductor 352B may be disposed alternately, and the n-type semiconductor 352A and the p-type semiconductor 352B may be connected in series through the connecting conductor CS1 provided on the third substrate 358A and the connecting conductor CS2 provided on the fourth substrate 358B. In this embodiment, the connecting conductor CS1, the connecting conductor CS2, the first electrode 354, and the second electrode 356 may be made of copper, but the disclosure is not limited thereto.

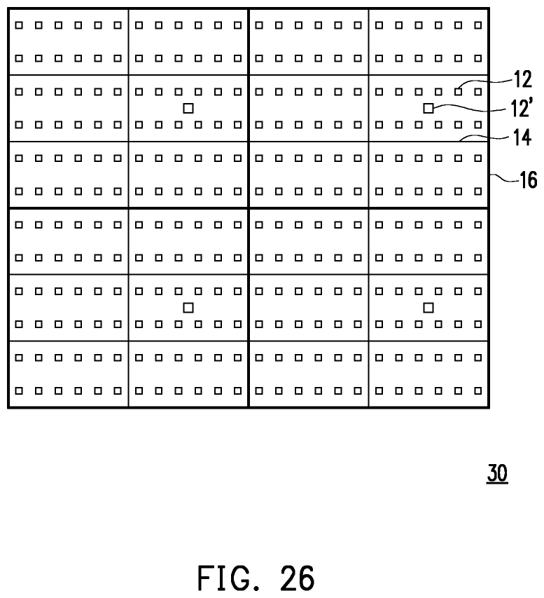

FIG. 26 is a schematic diagram of an electronic device according to still another embodiment of the disclosure. An electronic device 30 of FIG. 26 includes a plurality of light-emitting elements 12, a plurality of piezoelectric elements 14, and a plurality of temperature control elements 16, where the configuration, layout, structure, material, and cross-sectional structure of the light-emitting element 12 and the piezoelectric element 14 may be implemented by applying the design of the light-emitting element and the piezoelectric element in any of the foregoing embodiments. For example, the layout relationship between the light-emitting element 12 and the piezoelectric element may be as described in the embodiment of FIG. 1; the cross-sectional structure of the light-emitting element 12 and the piezoelectric element 14 may be as described in any one of the embodiments in FIG. 2 to FIG. 6 and FIG. 12 to FIG. 13; the manufacturing process of the light-emitting element 12 and the piezoelectric element 14 may be as described in the embodiments of FIG. 7 to FIG. 10 or FIG. 14 to FIG. 17; and the electrode design of the piezoelectric element 14 may be as shown in FIG. 11 or FIG. 18. In addition, the temperature control element 16 may be implemented by any embodiment disclosed in FIG. 20 to FIG. 25. Specifically, the main difference between the foregoing embodiment and the electronic device 30 is that the electronic device 30 further includes a light-emitting element 12′, where the light-emitting element 12′ is, for example, an infrared light-emitting diode capable of providing a heating effect and is adapted to provide temperature stimuli like the temperature control element 16. The arrangement relationship between the light-emitting element 12′ and the piezoelectric element 14 may be substantially the same as the arrangement relationship between the light-emitting element 12 and the piezoelectric element 14. In other words, the light-emitting element 12′ may be implemented by adopting the arrangement of the light-emitting element 12 in any one of the structures of FIG. 2, FIG. 12, and FIG. 13. In this embodiment, in addition to the temperature control element 16 which may be adapted to adjust the temperature of the electronic device 30 in different regions, the light-emitting element 12′ may also be adapted to heat a local area of the electronic device 30, such that the electronic device 30 is capable of providing variable temperature adjustments.

In summary, in addition to the light-emitting element, the electronic device of the embodiments of the present disclosure also includes at least one of a piezoelectric element and a temperature control element. In this way, in addition to providing visual stimuli, the electronic device may also provide the user with tactile and temperature stimuli, thereby enhancing the functions of the electronic device. Furthermore, in the embodiments of the disclosure, a plurality of piezoelectric elements and a plurality of temperature control elements are disposed in an electronic device in an array, and the piezoelectric elements and the temperature control elements may be controlled independently. In this way, the electronic device provides local tactile and temperature stimuli, thereby enriching the applications of the electronic device.

What is claimed is:

1. An electronic device, comprising:
a first substrate;
a second substrate;
a light-emitting element, disposed between the first substrate and the second substrate; and
a piezoelectric element, disposed between the first substrate and the second substrate, wherein the piezoelectric element comprises a piezoelectric layer, the piezoelectric layer comprises an opening, and the light-emitting element is provided in the opening.

2. The electronic device according to claim 1, wherein the piezoelectric element further comprises a first electrode and a second electrode, and the first electrode and the second electrode are adapted to control piezoelectric properties of the piezoelectric layer.

3. The electronic device according to claim 2, wherein the first electrode is provided between the piezoelectric layer and the first substrate, and the second electrode is provided between the piezoelectric layer and the second substrate.

4. The electronic device according to claim 2, wherein the first electrode and the second electrode are both provided between the piezoelectric layer and the second substrate.

5. The electronic device according to claim 4, wherein the first electrode comprises a first comb pattern, the second electrode comprises a second comb pattern, and the first comb pattern and the second comb pattern are disposed alternatively.

6. The electronic device according to claim 1, wherein the piezoelectric element further comprises a light-absorbing particle, and the light-absorbing particle is doped in the piezoelectric layer.

7. The electronic device according to claim 1, wherein numbers of the light-emitting element and the piezoelectric element are plural, and a configuration density of the light-emitting element may be greater than a configuration density of the piezoelectric element.

8. The electronic device according to claim 7, wherein a number of the opening in the piezoelectric layer is plural to accommodate the corresponding light-emitting element respectively.

9. The electronic device according to claim 1, further comprising a temperature control element, wherein the temperature control element comprises a thermoelectric module, and the thermoelectric module is disposed on a surface of the first substrate away from the second substrate.

10. The electronic device according to claim 9, wherein the piezoelectric element further comprises a first electrode and a second electrode, the thermoelectric module comprises an n-type semiconductor and a p-type semiconductor, and the n-type semiconductor and the p-type semiconductor are connected in series between the first electrode and the second electrode.

11. The electronic device according to claim 9, wherein numbers of the piezoelectric element and the temperature control element are plural, and a configuration density of the piezoelectric element is greater than a configuration density of the temperature control element.

12. The electronic device according to claim 1, wherein the light-emitting element further comprises a visible light-emitting element, an infrared light-emitting element, or both.

13. The electronic device according to claim 1, further comprising a light-absorbing layer, wherein the light-absorbing layer is disposed between the first substrate and the second substrate, and the light-absorbing layer is provided between the piezoelectric layer and the second substrate.

14. The electronic device according to claim 1, further comprising a light color adjustment layer disposed on a light-emission path of the light-emitting element.

15. The electronic device according to claim 1, further comprising a bank surrounding the light-emitting element and provided between the light-emitting element and the piezoelectric element.

16. An electronic device, comprising:
a first substrate;
a second substrate;
a plurality of light-emitting elements, disposed between the first substrate and the second substrate; and
a plurality of temperature control elements, disposed on a surface of the first substrate away from the second substrate, and the temperature control elements are controlled independently.

17. The electronic device according to claim 16, wherein each of the temperature control elements comprises a plurality of thermoelectric modules, each of the thermoelectric modules comprises an n-type semiconductor and a p-type semiconductor, and the thermoelectric modules are disposed in a plurality of rows.

18. The electronic device according to claim 17, wherein each of the temperature control elements further comprises a first electrode and a second electrode, and the n-type semiconductor and the p-type semiconductor are electrically connected in series and are connected between the first electrode and the second electrode.

19. The electronic device according to claim 17, further comprising a third substrate and a fourth substrate, wherein the thermoelectric modules are disposed between the third substrate and the fourth substrate, and the third substrate is attached to the surface of the first substrate.

20. The electronic device according to claim 19, wherein materials of the third substrate and the fourth substrate comprise insulating ceramic materials, Al₂O₃, AlN, or a combination thereof.
